(19) United States
(12) Patent Application Publication
(10) Pub. No.: US 2025/0391664 A1
(43) Pub. Date: Dec. 25, 2025

(54) Plasma Dicing for Multi-Tier Die for Die Strength Enhancement and Irregular Shaped Dicing

(71) Applicant: Apple Inc., Cupertino, CA (US)

(72) Inventors: Jimin Yao, Cupertino, CA (US); SivaChandra Jangam, Milpitas, CA (US); Sanjay Dabral, Cupertino, CA (US); Myung Jin Yim, San Jose, CA (US); Chi Nung Ni, Foster City, CA (US); Vidhya Ramachandran, Cupertino, CA (US); Young Doo Jeon, San Jose, CA (US); Jun Zhai, Cupertino, CA (US)

(21) Appl. No.: 19/067,524

(22) Filed: Feb. 28, 2025

Related U.S. Application Data
(60) Provisional application No. 63/662,738, filed on Jun. 21, 2024.

(51) Int. Cl. H01L 21/3065; B23K 26/364; H01L 21/78; H01L 23/00; H01L 23/31

(52) U.S. Cl. CPC H01L 21/3065; B23K 26/364; H01L 21/78; H01L 23/3178; H01L 24/08; H01L 24/80; H01L 2224/08135; H01L 2224/80894; H01L 2924/35121

(57) ABSTRACT

Integrated circuit (IC) structures methods of assembling an integrated circuit structure are described in which various etching sequences including plasma etching are utilized to remove direct bonded interfaces at die corners or edges that are at high-risk for non-bonding or delamination. In an embodiment, a laser etching operation is first performed to remove molding compound at local areas between adjacent components, following by a plasma dicing operation through the direct bonded structures.

### RELATED APPLICATIONS

This application claims the benefit of priority of U.S. Provisional Application No. 63/662,738, filed Jun. 21, 2024, which is herein incorporated by reference.

### BACKGROUND

### Field

Embodiments described herein relate to semiconductor packaging, and more particularly to dicing of directly bonded structures.

### Background Information

The current market demand for portable and mobile electronic devices such as mobile phones, personal digital assistants (PDAs), digital cameras, portable players, augmented reality/virtual reality (AR/VR) headsets, gaming, and other mobile devices requires the integration of more performance and features into increasingly smaller spaces. As a result, various multiple-die packaging solutions such as system in package (SiP) and package on package (PoP) have become more popular to meet the demand for higher die/component density devices.

There are many different possibilities for arranging multiple dies in an SiP. For example, vertical integration of dies in SiP structures has evolved into 2.5D solutions and 3D solutions. Hybrid bonding with metal-metal and dielectric-dielectric bonds using suitable techniques such as wafer-on-wafer (WoW) or chip-on-wafer (CoW) bonding is gaining more attention for mass production of high-density input/output (I/O) chips with ultra-small pad pitches. A traditional hybrid bonding sequence includes three main operations including dielectric-dielectric initial bonding at room temperature, heating to close dishing gap, and then further heating to compress metal-to-metal bonds. After the hybrid bonding process there can be follow up processing and device finishing operations depending upon the particular application. Modern integrated circuit (IC) fabrication techniques commonly utilize gap fill material such as dielectric materials (e.g., chemical vapor deposition oxide or nitrides) or epoxy molding compound to encapsulate the hybrid bonded dies for various reasons including to protect brittle material from mechanical damage and to smooth out a surface to facilitate downstream wafer-level processing and dicing.

### SUMMARY

Integrated circuit (IC) structures, electronic modules, and methods of fabrication are described in which direct bonded interfaces can be removed in regions, such as at die corners or edges, that are at high-risk for non-bonding or delamination. This may be accomplished with dicing methods, and in particular plasma etching optionally in combination with local laser etching. In an embodiment a method of assembling an integrated circuit (IC) structure, such as an electronic package, includes directly bonding one or more second-level components to a first-level electronic component. The second-level component(s) may be dies or dummy dies, for example. The first-level component may be an interposer, or also a die with larger footprint. The second-level component(s) may be hybrid bonded (for dies) or fusion bonded with a dielectric-dielectric bonding interface (for dummy dies). For example, this can be with CoW bonding or WoW bonding of a reconstituted wafer. Laser etching can then be performed through a gap fill material in local areas. For example, where there are multiple second-level components, the laser etching may be to remove the gap fill material from spaces laterally between adjacent second-level components. This may be followed by a plasma dicing operation first through the first-level electronic component and proceeding through the multiple second-level components. The plasma etching operation may additionally proceed through the local area where laser etching was performed to remove the gap fill material.

### BRIEF DESCRIPTION OF THE DRAWINGS

FIG. 1 is a schematic cross-sectional side view illustration of an integrated circuit structure including plasma diced edges in accordance with an embodiment.

FIGS. 2A-2C are schematic top layout views of dicing lanes through a plurality of molded second-level components in accordance with an embodiment.

FIG. 2D is a schematic top layout view of dicing lanes through a single molded second-level component in accordance with an embodiment.

FIG. 3A is a schematic cross-sectional side view illustration of dicing lanes through an IC structure taken along lines A-A of FIG. 2A in accordance with an embodiment.

FIG. 3B is a schematic cross-sectional side view illustration of dicing lanes through an IC structure taken along lines B-B of FIG. 2A in accordance with an embodiment.

FIG. 3C is a perspective view illustration of a diced edge taken along lines C-C of FIG. 2A in accordance with an embodiment.

FIG. 3D is a perspective view illustration of a diced edge including a plasma etched notch in accordance with an embodiment.

FIG. 4A is a close-up schematic top view illustration of diced edges of an electronic component in accordance with an embodiment.

FIG. 4B is a close-up schematic top view illustration of a diced edge including a plasma etched notch in accordance with an embodiment.

FIG. 5 is a close-up schematic top view illustration of diced edges of an electronic component in accordance with an embodiment.

FIGS. 6A-6D are composite cross-sectional side view illustrations for a full-cut plasma dicing method of assembling an integrated circuit structure with local laser etching in accordance with an embodiment.

FIGS. 6E-6G are composite cross-sectional side view illustrations for a full-cut plasma dicing method of assembling an integrated circuit structure with local laser etching in accordance with an embodiment.

FIGS. 7A-7B are composite cross-sectional side view illustrations for a half-cut plasma method of assembling an integrated circuit structure with mechanical sawing in accordance with an embodiment.

FIG. 7C is a schematic top layout view of dicing lanes through a plurality of molded second-level components of the half-cut plasma method of FIGS. 7A-7B in accordance with an embodiment.

FIG. 7D is a perspective view illustration of plasma diced edges and saw cut edges spanning across two molded second-level components of the half-cut plasma method of FIGS. 7A-7B in accordance with an embodiment.

FIGS. 8A-8C are composite cross-sectional side view illustrations for a half-cut plasma method of assembling an integrated circuit structure with local laser etching and mechanical sawing in accordance with an embodiment.

FIG. 8D is a schematic top layout view of dicing lanes through a plurality of molded second-level components of the half-cut plasma method of FIGS. 8A-8C in accordance with an embodiment.

FIG. 8E is a perspective view illustration of plasma diced edges and saw cut edges spanning across two molded second-level components of the half-cut plasma method of FIGS. 8A-8C in accordance with an embodiment.

FIGS. 9A-9D are cross-sectional side view illustrations for a method of assembling an integrated circuit structure including plasma dicing prior to molding in accordance with an embodiment.

FIGS. 10A-10D are cross-sectional side view illustrations for a method of assembling an integrated circuit structure including plasma dicing prior to molding in accordance with an embodiment.

### DETAILED DESCRIPTION

Embodiments describe integrated circuit (IC) structures, electronic modules, and methods of fabrication. In an embodiment, a method of assembling an integrated circuit structure (e.g., electronic package) includes directly bonding a first second-level bonding surface of a first second-level component to a first-level bonding surface of a first-level electronic component, and directly bonding a second second-level bonding surface of a second second-level component to the first-level bonding surface of the first-level electronic component. For example, the first-level electronic component may be a die or interposer, and the second-level components can be dies, dummy dies, etc. Second-level dies may be hybrid bonded to the first-level electronic component, and second-level dummy dies, integrated to maximize plasma dicing lanes, can be silicon chiplets for example that are fusion bonded (e.g., dielectric-dielectric bonds such as silicon oxide, silicon nitride, silicon carbon nitride, etc.) to the first-level electronic component. As such, bonding may be characterized as chip-on-wafer (CoW) bonding and can be followed by encapsulating the first second-level component and the second second-level component with a gap fill material on the first-level bonding surface. This may be followed by a planarization and thinning operation along the back sides of the second-level components and gap fill material. It is to be appreciated that arrays of a plurality of second-level components can be bonded.

While embodiments are described and illustrated primarily with regard to multiple second-level components bonded to a first-level electronic component, it is to be appreciated that the embodiments are not so limited, and the dicing sequences described herein can also be applied to single second-level components bonded to a first-level electronic component. Furthermore, while the fabrication sequences describe CoW fabrication, the fabrication sequences (including hybrid bonding and fusion bonding) can be practiced with WoW fabrication, particularly with a reconstituted wafer of second-level components, and optionally a reconstituted wafer of first-level electronic components. The dicing techniques described herein can be applied to a variety of directly bonded structures.

The gap fill material can be formed of any suitable material, including dielectric materials (e.g., oxides such as silicon oxide), silicon materials, and organic materials inclusive of various molding compound materials such as epoxy molding compound. Where the gap material is formed of an inorganic material such as, but not limited to, silicon oxide or silicon, plasma dicing techniques can be utilized for IC structure (package) singulation, where plasma dicing lanes can proceed through any of the first-level electronic component, second-level components and gap fill material. Where the gap fill material is formed of an organic material, specialized gas mixtures or sequences, may be utilized to achieve an etch selectivity with both organic and inorganic materials. In other embodiments local laser etching may be included to remove organic gap fill material from select regions.

In an embodiment localized deep laser spot etching can be performed to remove the organic gap fill material (e.g., molding compound) from spaces laterally between the second-level components, and only in local areas. The bonded and gap-filled (molded) structure can then be flipped, and plasma etched (and diced) from a second side of the first-level electronic component that is opposite the first-level bonding surface. Specifically, plasma dicing can then be performed completely through the first-level electronic component, the first second-level component, and the second second-level component to singulate the integrated circuit structure. In this manner, dicing lanes can proceed through semiconductor and inorganic layers, and intersect the local areas where molding compound has already been removed. Thus, plasma dicing need not proceed through organic (e.g., molding compound) or metal layers which may not be as easily etched. Such a dicing sequence can be considered a full-cut plasma dicing technique with local laser etching. In other embodiments half-cut plasma dicing techniques can be utilized where plasma etching/dicing is performed partially through the direct bonded interface, followed by option local laser etching and mechanical saw dicing.

In one aspect, it shas been observed that direct bonded (e.g., hybrid bonded, fusion bonded) interface reliability for die-to-die or die-to-interposer interfaces can be affected by die corner weakness and mold-die interaction. For example, gap fill materials, and particularly molding compound material such as epoxy molding compound (EMC), can have a much lower elastic modulus and higher coefficient of thermal expansion (CTE) than the die(s) it encapsulates, and this change in elastic modulus and CTE from the bonded die(s) to the surrounding gap fill material can cause high stress concentrations near the die edges and corners of the bonding interface. In particular high peeling stress concentrations may form when the bonded structure is trying to bend due to thermal or mechanical loadings, such as with EMC expansion at elevated temperatures. Additionally, high shear stress concentrations may form as the bonded structure tries to shrink or expand together with other packaging and system components (e.g., substrate, printed circuit board, etc.).

In another aspect it has been observed that an incoming die may have a certain level of intrinsic warpage due to residual stress in a back-end-of-the-line (BEOL) build-up structure and bonding interface layer material that is used for fusion or hybrid bonding. It has been observed that it can be challenging to flatten the die edges and corners during direct bonding processes such as fusion and hybrid bonding.

In accordance with embodiments, the bonded interface can be removed in high-risk regions such as at die corners and edges. This may be accomplished with dicing methods (e.g., plasma, laser, mechanical sawing) to remove the high-risk regions for non-bonding or delamination. In particular, the dicing methods in accordance with embodiments can primarily leverage plasma dicing, with lesser reliance (or none) on laser etching or grooving and mechanical sawing. In particular, it has been observed that the deep grooves formed during laser grooving/etching can burn the target layers, causing damage and also generate a significant amount of heat, which can also cause damage such as (but not limited to) delamination and crack propagation, particularly in the BEOL dielectric layers. Furthermore, laser grooving/etching can generate laser recast, which can be a source for future defect generation. In accordance with some embodiments described herein, laser grooving or etching may be limited to local areas, and this may be followed or preceded by plasma dicing.

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “over”, “to”, “between”, “spanning” and “on” as used herein may refer to a relative position of one layer with respect to other layers. One layer “over”, “spanning” or “on” another layer or bonded “to” or in “contact” with another layer may be directly in contact with the other layer or may have one or more intervening layers. One layer “between” layers may be directly in contact with the layers or may have one or more intervening layers.

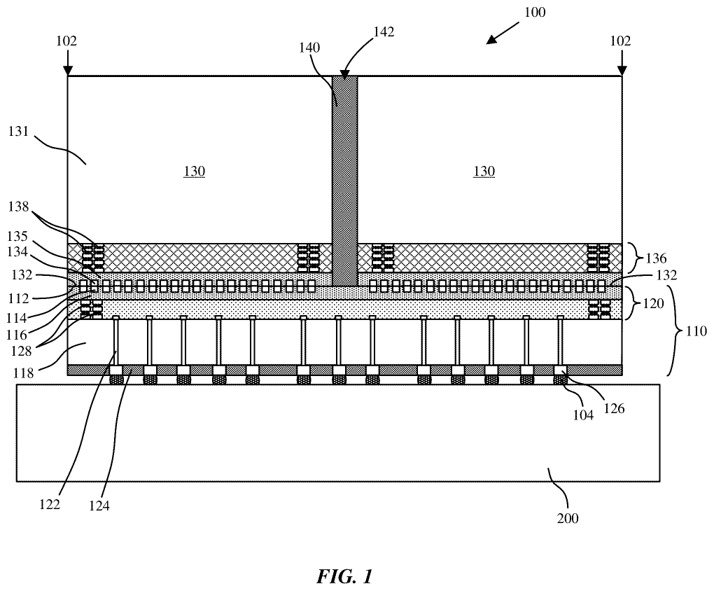

Referring now to FIG. 1 a schematic cross-sectional side view illustration is provided of an integrated circuit (IC) structure 100 including plasma etched sidewall 102 in accordance with an embodiment. The IC structure may be an electronic package for example, that can be further flip chip mounted onto a module substrate 200 with solder bumps 104. The IC structures 100 in accordance with embodiments can include a first-level electronic component 110 and one or more second-level components 130 including second-level bonding surfaces 132 bonded directly to a first-level bonding surface 112 of the first-level electronic component 110. A gap fill material 140 may additionally be laterally adjacent to the one or more second-level components 130 and fill any spaces 142 laterally between the plurality of second-level components 130. It is to be appreciated that while two second-level components 130 are illustrated, that this is merely exemplary, and that a single second-level component may be include or more than two may be included.

The second-level components 130 in accordance with embodiments can be the same or different type of components (e.g., dies). Various exemplary dies include system-on-chip (SOC), graphics processing unit (GPU), central processing unit (CPU), artificial intelligence (AI), machine learning logic, radio-frequency (RF) baseband processor, radio-frequency (RF) antenna, signal processors, power management integrated circuit (PMIC), logic, memory, photonics, biochips, low speed and/or high speed input/output (HSIO), cache, a silicon interconnect and any combinations thereof. The second-level components 130, or dies, in accordance with embodiments may be active or passive, and may be an interposer. The second-level components 130 can also be dummy dies (e.g., silicon chiplets).

In accordance with embodiments second-level components 130 can be directly bonded to the first-level electronic component 110, which can also be a die or interposer structure. For example, direct bonding may be with fusion bonding (dielectric-dielectric bonds) or hybrid bonding (metal-metal bonds and dielectric-dielectric bonds). The dielectric materials used for hybrid and/or fusion bonding can be either inorganic-based or organic-based materials. The first-level electronic component 110 can include electrical routing, inclusive of die-to-die routing, and vertical routing from the second-level components to the module substrate 200. The first-level electronic component 110 may optionally include various passive or active devices. In a particular embodiment the second-level components 130 include multiple CPUs and a GPU, hybrid bonded with an interposer first-level electronic component 110. The IC structure 100 may be connected to multiple memory packages as electronic components and connected through the module substrate 200.

As shown, the first-level electronic component 110 can include a first-level bonding surface 112, a plurality of metal bond pads 114, and dielectric bonding layer 116. Similarly, the one or more second-level components 130 can each include a second-level bonding surfaces 132, a plurality of metal bond pads 134 and dielectric bonding layer 135. The first-level electronic component 110 may also include a semiconductor layer 118 (which can also be a bulk layer formed of silicon) and BEOL build-up structure 120. Alternatively, semiconductor layer 118 can be substituted with another bulk material such as glass. The BEOL build-up structure 120 may include electrical routing, an optional seal ring 128, and optionally die-to-die routing between the second-level components. A plurality of through vias 122 (e.g., through silicon vias, through glass vias, etc.) can extend through the semiconductor layer 118 and backside dielectric layer 124 to make contact with terminals 126, onto which solder bumps (which can also be solder tips) 104 can be placed. It is to be appreciated that the particular illustration provided is for illustrational purposes, and the first-level electronic component 110 can assume a variety of structures. For example, the first-level electronic component can be a cored substrate, a coreless substrate, rigid, flexible, etc. as well as be a die, or reconstituted die structure.

Still referring to FIG. 1, the second-level components 130 can each include a semiconductor layer 131, and optional back-end-of-the-line (BEOL) build-up structure 136 on the semiconductor layer. The semiconductor layer 131 can be a bulk silicon substrate, silicon-on-insulator (SOI) substrate, etc. and may have an epitaxial device layer over bulk silicon. Silicon is exemplary, and other semiconductor substrate materials can be used. The BEOL build-up structure 136 may include electrical routing as is customary, as well as metal sealing structures (e.g., seal rings) 138 to function as both as a physical barrier to moisture and impurity ingress, as well as to provide mechanical integrity. The BEOL build-up structure 136 may include a plurality of metal wiring layers and dielectric layers, commonly referred to as interlayer dielectrics (ILD), as common in microelectronic manufacturing.

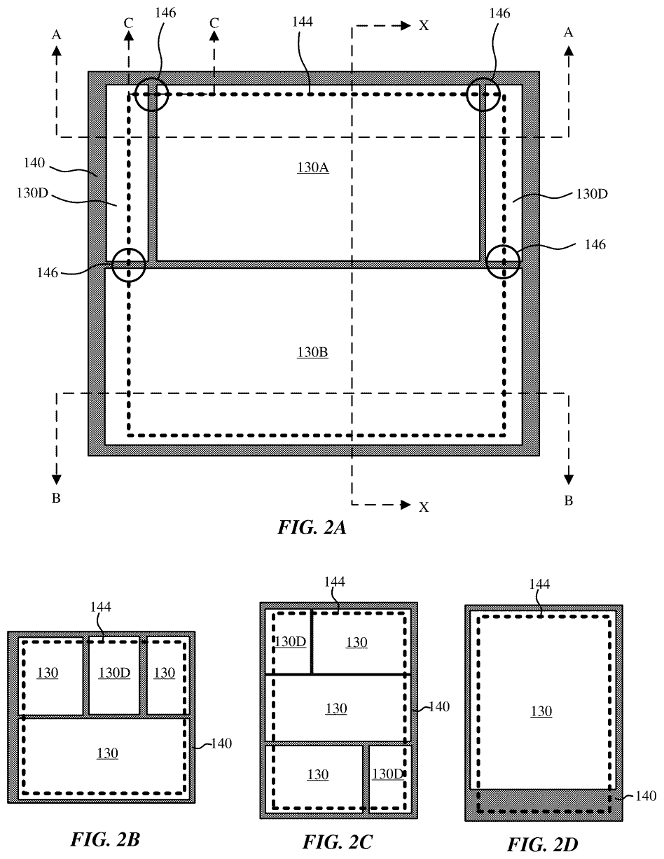

FIG. 2A is a schematic top layout view of dicing lanes 144 through a plurality of molded second-level components in accordance with an embodiment. Referring briefly back to FIG. 1, the IC structures 100, or electronic packages, can be assembled at wafer-scale or panel-scale where a plurality of second-level components 130 are bonded directly to an underlying substrate, such as a processed panel or processed wafer including a plurality of areas of first-level electronic components 110. A molding process can then be performed where the gap fill material 140 laterally surrounds the plurality of second-level components 130 and fills spaces therebetween, followed by a dicing/singulation sequence to form a plurality of IC structures 100, or electronic packages, from the assembled structure. The schematic cross-sectional side view illustration of FIG. 1 can be along section X-X of FIG. 2A after dicing/singulation where plasma etched sidewalls 102 are formed along dicing lanes 144.

In accordance with embodiments, the plurality of second-level components, and specifically the dies thereof, may not always be the same size (e.g., area/footprint), which can ordinarily result in dicing/singulation through gap fill material 140. This surrounding gap fill material 140, such EMC, can cause high stress concentrations near the second-level components (die) edges and corners of the bonding interface. This can be exasperated along diced edges of the dies prior to CoW hybrid bonding, where such dicing is commonly performed with wafer sawing. In accordance with embodiments, the wafer-sawed second-level component edges can be further diced/singulated during packaging using a plasma etching sequence which can be less harmful, and can also remove non-bond areas along the edges after CoW hybrid bonding. Where the hybrid bonded second-level components (e.g., dies) are of different sizes/areas one or more dummy second-level components 130D can also be bonded to the first-level electronic component to provide additional material that can be plasma etched, since it has been observed that traditional plasma etching compositions utilized for etching of semiconductor and inorganic dielectric materials have much less etch selectivity for organic materials used for the gap fill material, such as EMC. Nevertheless, local areas 146 of the organic gap fill material 140 remain, which may optionally be removed with local deep laser spot etching in accordance with embodiments prior to plasma etching for IC structure (package) singulation.

It is to be appreciated that the particular arrangement of second level components provided in FIG. 2A is exemplary and embodiments are applicable to other arrangements and different numbers of dies and dummy dies, as shown in FIG. 2B and FIG. 2C. In the embodiment illustrated in FIG. 2D a single second-level component 130 is bonded to the first-level electronic component and encapsulated with a gap fill material 140. The dicing lanes can be entirely contained within a footprint of the second-level component 130, or extend outside of the second-level component 130 and through the gap fill material 140 as shown. Furthermore, while rectangular dicing lanes are illustrated, embodiments are not so limited and irregular shaped dicing lanes can be achieved with plasma dicing. A variety of configurations are contemplated.

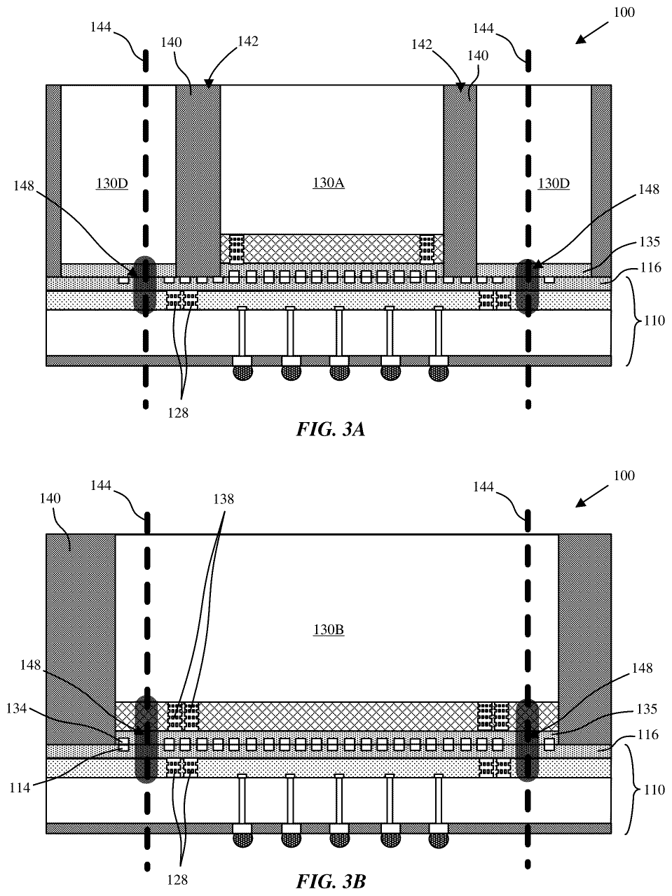

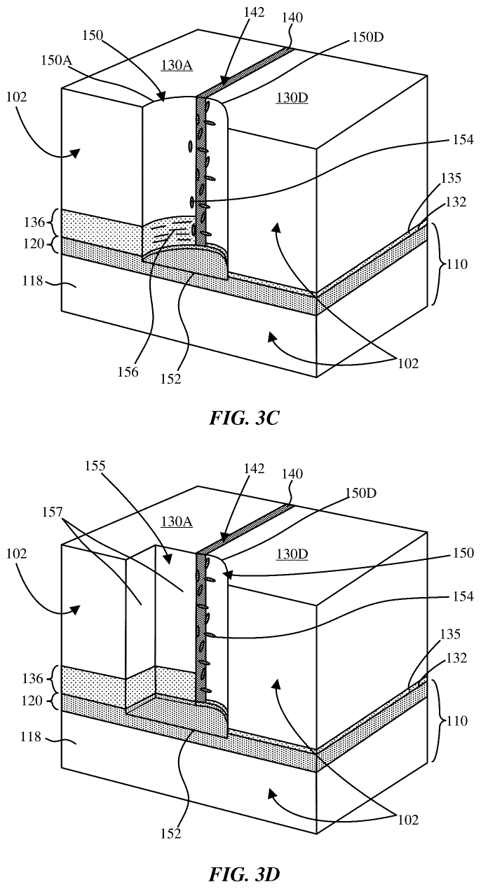

Referring now to FIGS. 3A-3B, FIG. 3A is a schematic cross-sectional side view illustration of dicing lanes 144 through an IC structure taken along lines A-A of FIG. 2A in accordance with an embodiment; FIG. 3B is a schematic cross-sectional side view illustration of dicing lanes through an IC structure taken along lines B-B of FIG. 2A in accordance with an embodiment. The illustrations of FIGS. 3A-3B are substantially similar to that of FIG. 1, with one difference being that the illustrations are a close-up view of an electronic component prior to dicing from wafer-level or panel-level fabrication. As shown, the dicing lanes 144 in FIG. 3A can proceed through the first-level electronic component 110 (e.g., interposer or die) and second-level components 130D, which are dummy dies that have been fusion bonded to the first-level electronic component 110 with dielectric-dielectric bonds (e.g., silicon oxide, silicon nitride, silicon carbon nitride, etc.). Further, the dicing lanes in FIG. 3B can proceed through the first-level electronic component 110 (e.g., interposer or die) and second-level component 130B, or die that is hybrid bonded to the first-level electronic component 110. As shown, metal bond pads 134, 114 may be located outside of the dicing lanes 144 to assist with bonding prior to singulation. As shown, the dicing lanes 144 proceed through metal-free zones 148 in the bonded components to facilitate etching of the semiconductor and dielectric materials forming the first-level electronic component and second-level components. Plasma etching can be performed using a suitable gas mixtures such as, but not limited to, CF₄/H₂, CF₄/O₂/N₂, SF₆/O₂/N₂, SF₆/CH₄/N₂ and SF₆/CH₄/N₂/O₂.

While the dicing lanes 144 illustrated in FIGS. 3A-3B proceed through the stacked components, the dicing lanes 144 may intersect with local areas 146 of gap fill material 140 filling the spaces between adjacent second-level components as shown in FIG. 2A. In some embodiments the plasma etching chemistries and methods may be adjusted to etch both the gap fill material and stacked components. In such instances plasma etching may process through gap fill material laterally adjacent to a second-level component, and not necessarily be limited to the local areas 146 filling spaces between adjacent second-level components. In other embodiments, particularly when the gap fill material is an organic (e.g., molding compound), localized deep laser spot etching may be employed at the local areas 146 to locally remove the organic gap fill material 140 from a space 142 laterally between adjacent second-level components. Furthermore, the localized deep laser spot etching need only be wide enough for process control, and to accommodate the plasma dicing lanes 144.

FIG. 3C is a perspective view illustration of a diced edge taken along lines C-C of FIG. 2A in accordance with an embodiment. As shown, the gap fill material 140 is on the first-level bonding surface 132 and fills the space 142 laterally between a first second-level component 130A (e.g., die) and the second second-level component 130D (e.g., dummy die). A plasma etched sidewall 102 spans across an entire thickness of the first-level electronic component 110, the first second-level component 130A and the second second-level component 130D. Additionally, a laser etched sidewall 150 extends across an entire thickness of the gap fill material 140 (e.g., molding compound) laterally between the first second-level component 130A and the second second-level component 130D, and terminates on the first-level electronic component.

As shown, the laser etched sidewall 150 can be a vertical cavity that extends internally into the integrated circuit structure from the plasma etched sidewall 102. Specifically, the laser etched sidewall 150 is shown as a half cylinder shape. It is to be appreciated that the particular illustration provided in FIG. 3C is not to scale, and that certain features may be enlarged and emphasized for illustrational purposes only. In order to ensure complete gap fill material 140 removal the localized deep laser spot etching may over-etch slightly. For example, a portion of the laser etched sidewall 150 may extend through (past) the first-level bonding surface 132 and into the first-level electronic component. This may result in a bottom surface 152 below the first-level bonding surface 132. The laser etched sidewall 150 may also extend slightly into one or both of the second-level components. As shown, a first portion 150A of the laser etched sidewall 150 extends laterally into the first second-level component 130A and spans across an entire thickness of the first-level electronic component. Similarly, a second portion 150D of the laser etched sidewall 150 can extend laterally into the second second-level component 130D and spans across an entire thickness of the second second-level component. Laser etching may additionally result in recast gap fill material 154 (e.g., recast organic material) on the laser etched sidewall. Furthermore, the recast gap fill material 154 can be on different portions of the laser etched sidewall 150, including on the etched gap fill material 140, as well as on the first portion 150A and the second portion 150D. Laser etching may additionally create a higher defect density in BEOL build-up structures 136 along the laser etched sidewalls 150 compared to the plasma etched sidewalls 102. Defects 156 can include cracks and delamination, for example. As shown, the defect density within the BEOL build-up structure 136 laterally adjacent to the laser etched sidewall 150 is greater than a defect density within the BEOL build-up structure laterally adjacent to the plasma etched sidewall 102.

It is to be appreciated that while the particular illustration provided in FIG. 3C is with regard to laser etching to remove the gap fill material between a die and dummy die, that this is exemplary and laser etching can be performed between adjacent dies, or adjacent dummy dies. Furthermore, the dummy dies may be fusion bonded to the first-level electronic component 110 with dielectric-dielectric bonding, such as, but not limited to oxide-oxide bonding. Fusion bonding can be achieved with both inorganic and organic based dielectrics. More commonly dummy dies used for singulation purposes may be attached with organic adhesive materials. However, in accordance with embodiments the dicing lanes are designed to proceed through semiconductor and inorganic materials, avoiding metal and mitigating organic material. Alternatively, since the bonding layer thickness may be thin compared to the second-level components, plasma discing can also proceed through organic adhesive materials.

Referring now to FIG. 3D, the plasma etched sidewalls 102 can additionally be notched, such that the diced edge of the electronic component includes a plasma etched notch 155 in accordance with an embodiment. As shown, a plasma etched recess sidewall 157 can be recessed into the plasma etched sidewall 102. In this fabrication sequence the plasma etched recess sidewall 157 spans across an entire thickness of the first second-level component 130A and intersects with the laser etched sidewall 150 (as shown with the second portion 150D). In this manner, the defects shown in FIG. 3C can be removed using an irregular shaped plasma dicing pattern.

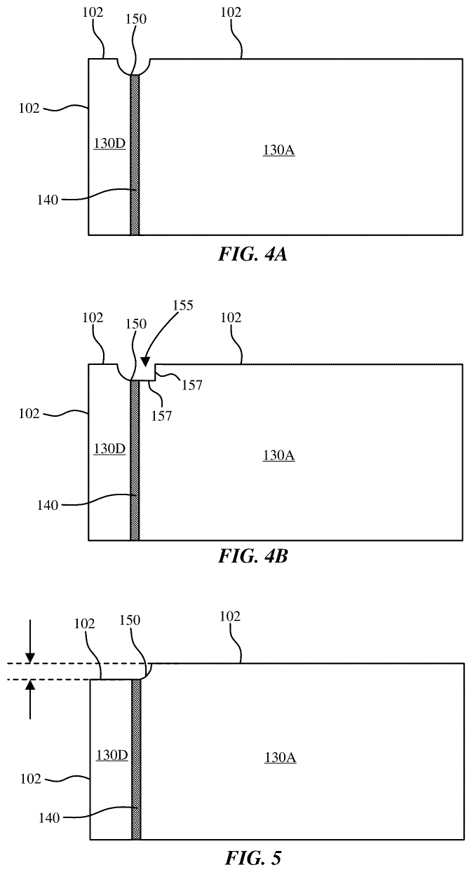

Referring now to FIGS. 4A-5, close-up schematic top view illustrations are provided of diced edges of an electronic component in accordance with an embodiment. The close-up illustration of FIG. 4A is similar to that illustrated in FIG. 2A and FIG. 3C, including substantially coplanar plasma etched sidewalls 102 that intersect the laser etched sidewall 150. The close-up illustration in FIG. 4B is similar to that illustrated in FIG. 3D, including a plasma etched notch 155 and plasma etched recess sidewalls 157. Substantially coplanar plasma etched sidewalls 102 are not required, and the plasma etched sidewalls 102 on opposite sides of a laser etched sidewall 150 can be offset from one another as shown in FIG. 5, and need not be parallel. Furthermore, the laser etched sidewall 150 need not be half cylindrical, and can assume other shapes or patterns, including planes and curved surfaces.

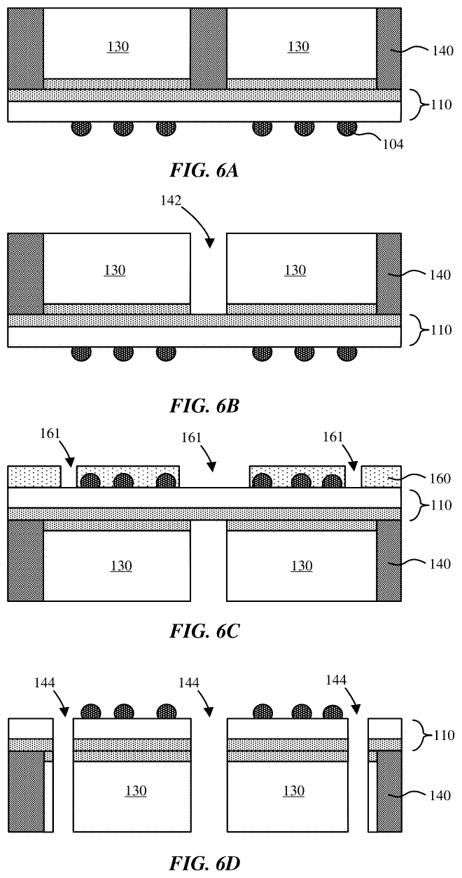

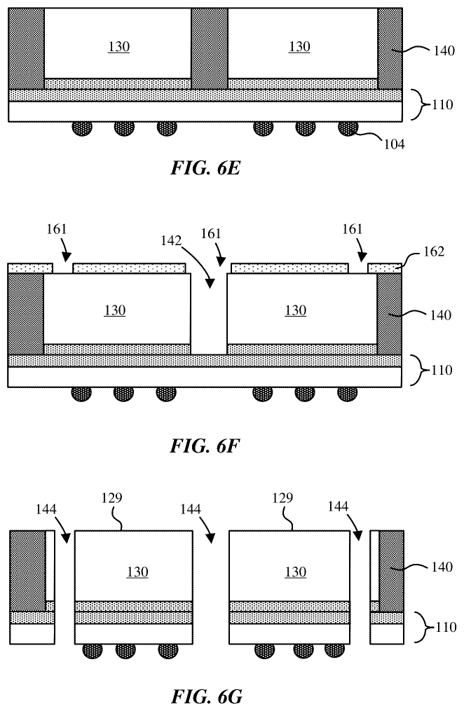

FIGS. 6A-6D are composite cross-sectional side view illustrations for a full-cut plasma etching method of assembling an integrated circuit structure with local laser etching in accordance with an embodiment. It is to be appreciated that the composite illustration is not a cross-sectional view and instead incorporates several different areas previously described into the same illustration. Furthermore, while multiple second-level components are illustrated the process sequence can be performed with a single second-level component, or more than two. Referring to FIG. 6A the sequence can begin with directly bonding a first second-level bonding surface of a first second-level component 130 to a first-level bonding surface of a first-level electronic component 110, and directly bonding a second second-level bonding surface of a second second-level component 130 to the first-level bonding surface of the first-level electronic component. It is to be appreciated that arrays of second-level components can be bonded to the first-level electronic component, which can be a proceed panel or wafer including arrays of interposers or dies. The processed panel or processed wafer may also be a reconstituted structure. The various second-level components can be dies, dummy dies etc. and may be directly bonded using suitable techniques such as hybrid bonding or fusion bonding.

The second-level components are then encapsulated in a gap fill material 140. As shown in FIG. 6B. It is to be appreciated that while the process sequence illustrated is for CoW fabrication, that WoW bonding with a reconstituted wafer including second-level components and gap fill material is also possible. From the back sides of the second-level components, the gap fill material 140 can then optionally be laser etched in a local area to remove the gap fill material from a space 142 laterally between the adjacent second-level components. For example, laser etching may optionally be utilized when the gap fill material is an organic material.

The structure can then be flipped followed by forming a mask layer 160 over a second side of the first-level electronic component that is opposite the first-level bonding surface. As shown in FIG. 6C the mask layer 160 covers the solder bumps 104, and is patterned to form openings 161 that will correspond to dicing lanes 144. A plasma dicing operation may then be formed from the second side of the first-level electronic component and completely through the first-level electronic component and second-level components to singulate the IC structure (e.g., package) as shown in FIG. 6D, followed by removal of the mask layer 160. The dicing lanes 144 may be through metal-free zone to facilitate plasma etching. As shown in FIGS. 6C-6D, the center dicing lane 144 can intersect the local area where gap fill material was removed by laser etching. The dicing sequence illustrated in FIGS. 6A-6D may be considered a full-cut plasma dicing sequence since plasma etching is used for etching of substantially the entire thickness of all components, with local laser etching only optionally used for local areas. In some embodiments, the plasma gas mixtures and sequences are controlled for dicing through the gap fill material without local laser etching.

FIGS. 6E-6G are composite cross-sectional side view illustrations for a full-cut plasma etching method of assembling an integrated circuit structure with local laser etching in accordance with an embodiment. It is to be appreciated that the composite illustration is not a cross-sectional view and instead incorporates several different areas previously described into the same illustration. Furthermore, while multiple second-level components are illustrated the process sequence can be performed with a single second-level component, or more than two. As shown in FIG. 6E and FIG. 6F the process sequence can begin similarly as described with regard to FIG. 6A and FIG. 6B. As shown, a mask layer 162 can be formed either before or after local laser etching to remove the gap fill material 140 from a space 142 laterally between the adjacent second-level components. The mask layer can be patterned to form openings 161 that will correspond to dicing lanes 144. As shown in FIG. 6G a plasma dicing operation may then be formed from a back side 129 of the second-level components, through the second-level components and the first-level electronic component 110 to singulate the IC structure, followed by removal of the mask layer 162. As shown in FIGS. 6E-6G, the center dicing lane 144 can intersect the local area where gap fill material was removed by laser etching. The dicing sequence illustrated in FIGS. 6E-6G may be considered a full-cut plasma dicing sequence since plasma etching is used for etching of substantially the entire thickness of all components, with local laser etching only optionally used for local areas. In some embodiments, the plasma gas mixtures and sequences are controlled for dicing through the gap fill material without local laser etching.

While plasma etching methods can a used for dicing a full thickness of the IC structure, in other embodiments plasma etching may be used to etch through a thickness of the direct bonded interface, followed by final dicing with other dicing solutions such as mechanical saw dicing. Such-half cut solutions may also provide high quality plasma diced edges along the bonding interface and low strength dielectric layers within routing layers near the direct bonded interface, while final dicing using mechanical sawing at higher throughput.

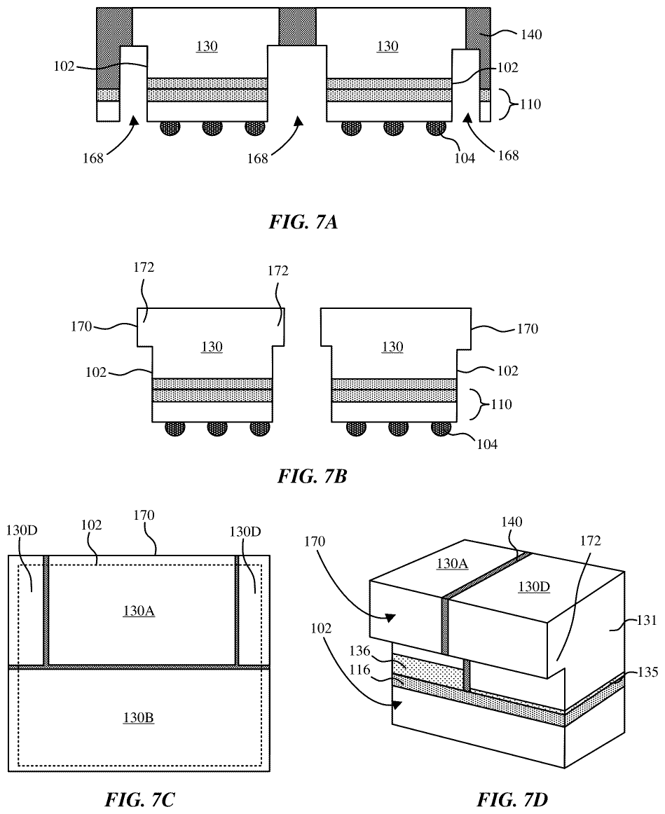

FIGS. 7A-7B are composite cross-sectional side view illustrations for a half-cut plasma method of assembling an integrated circuit structure with mechanical sawing in accordance with an embodiment. Referring to FIG. 7A the dicing sequence can begin with plasma etching of trenches 168 through a back side of the first-level electronic component 110 including solder bumps 104, and past the bonding interface between the first-level electronic component 110 and the second-level components 130. While multiple second-level components are illustrated the process sequence can be performed with a single second-level component, or more than two. This may be a multiple-step plasma etching sequence with different gas mixtures to accommodate etching through the various materials of the first-level electronic component, second-level electronic components 130 and gap fill material 140. Plasma etching may be facilitated where gap fill material 140 is formed of an inorganic material (e.g., dielectric, semiconductor), though specialized gas mixtures may be potentially used to achieve sufficient organic etch selectivity. This may be followed by a mechanical saw dicing operation as shown in FIG. 7B resulting in outer diced edges 170.

Referring now to FIGS. 7C-7D, FIG. 7C is a schematic top layout view of dicing lanes through a plurality of molded second-level components of the half-cut plasma method of FIGS. 7A-7B in accordance with an embodiment; FIG. 7D is a perspective view illustration of plasma diced edges and saw cut edges spanning across two molded second-level components of the half-cut plasma method of FIGS. 7A-7B in accordance with an embodiment. As shown, the half-cut plasma method may result in an IC structure (package) where the outer diced edges 170 completely surround the plasma etched sidewalls 102. Furthermore, a roof 172 may be formed in the semiconductor layer 131 as a result. Furthermore, the outer diced edges 170 may be limited to (bulk) semiconductor layer 131 of the second-level components and gap fill material 140 filling spaces therebetween. The plasma etched sidewalls 102 may extend completely through the first-level electronic component 110, and optionally past the BEOL build-up structure 136 of the second-level components (when present) to provide lower defect density than would be expected with mechanical saw dicing.

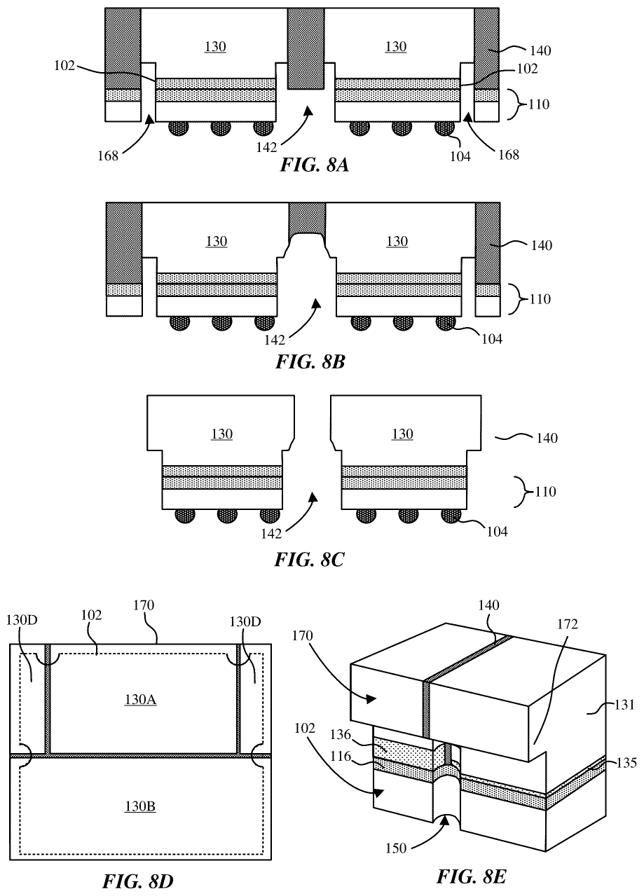

FIGS. 8A-8C are composite cross-sectional side view illustrations for a half-cut plasma method of assembling an integrated circuit structure with local laser etching and mechanical sawing in accordance with an embodiment. Referring to FIG. 8A the dicing sequence can begin with plasma etching of trenches 168 through a back side of the first-level electronic component 110 including solder bumps 104, and past the bonding interface between the first-level electronic component 110 and the second-level components 130. While multiple second-level components are illustrated the process sequence can be performed with a single second-level component, or more than two. This may be a multiple-step plasma etching sequence with different gas mixtures to accommodate etching through the various materials of the first-level electronic component and second-level electronic components 130. In the particular embodiment illustrated in FIG. 8A, the plasma etch selectivity to the gap fill material 140 may be significantly less, resulting in ineffective removal of the gap fill material (e.g., organic material, such as molding compound material). In particular, the gap fill material 140 may remain in spaces 142 between adjacent second-level components 130. As shown in FIG. 8A, the plasma etched sidewalls 102 are along what will be the exterior perimeter of the singulated IC structure. Referring to FIG. 8B local laser etching may then be utilized to remove the gap fill material 140 from the spaces 142 between adjacent second-level components 130. This may be followed by a mechanical saw dicing operation as shown in FIG. 8C resulting in outer diced edges 170.

Referring now to FIGS. 8D-8E, FIG. 8D is a schematic top layout view of dicing lanes through a plurality of molded second-level components of the half-cut plasma method of FIGS. 8A-8C in accordance with an embodiment; FIG. 8E is a perspective view illustration of plasma diced edges and saw cut edges spanning across two molded second-level components of the half-cut plasma method of FIGS. 8A-8C in accordance with an embodiment. As shown, the structure may be substantially similar to that illustrated in FIGS. 7C-7D, with a difference being the laser etched sidewall 150 that extends completely through a thickness of the first-level electronic component and into the second-level components, as well as the gap fill material. Similar structural artifacts may also exist as previously described such as higher defect densities in the BEOL build-up structure 136, recast, etc. The laser etched sidewall 150 may extend to the roof 172 of the semiconductor layer 131. While the plasma etched sidewalls 102 illustrated in FIGS. 8D-8E are flat sidewalls (e.g., for rectangular-shaped structure) this is not required, and a plasma etched notch 155 and plasma etched recess sidewalls 157 that are recessed into the plasma etched sidewall 102 can be formed similarly as with FIG. 3D and FIG. 4B.

Up until this point embodiments have described IC structures and methods of fabrication in which plasma dicing is performed after encapsulation of the second-level components with the molding compound. Additional fabrication sequences are envisioned where plasma dicing can be performed prior to molding to further limit laser exposure.

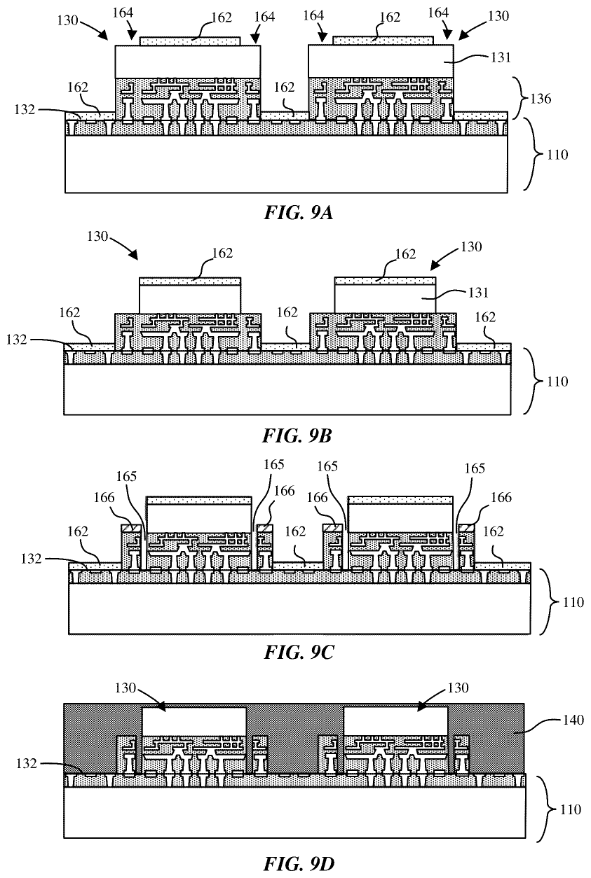

FIGS. 9A-9D are cross-sectional side view illustrations for a method of assembling an integrated circuit structure including plasma etching prior to molding in accordance with an embodiment. As shown, in FIG. 9A one or more second-level components 130 can be hybrid bonded to a first-level electronic component 110, followed by deposition and patterning of a mask layer 162 for plasma etching. As shown, the mask layer 162 may completely cover exposed first-level bonding surface 132, and only partially cover the second-level components 130 so that edge regions 164 of the second-level components are exposed. Specifically, the back sides of the one or more second-level components formed of bulk semiconductor material (e.g., silicon) are exposed. A plasma etching operation may then be performed as shown in FIG. 9B to remove the exposed bulk silicon edge regions of the second-level components 130, with plasma etching stopping at the BEOL build-up structure 136. Referring now to FIG. 9C, a second mask layer 166 is then formed partly over the exposed BEOL build-up structure 136, leaving an interior gap surrounding the bulk silicon region. Plasma etching is then continued using the mask layers 162, 166 to remove the dielectric layers of the BEOL build-up structure 136, forming trenches 165 that stop on the first-level bonding surface 132, or minimally are etched past the first-level bonding surface 132. Slight over etch may result in recesses (e.g., several microns or less deep) around the plasma etched sidewalls 102 of the second-level components. The second-level components 130 can then be encapsulated in gap fill material 140 (e.g., molding compound) as shown in FIG. 9D, which can also fill the trenches 165 and recesses. Downstream IC structure (package) singulation/dicing can then be performed using traditional singulation techniques such as sawing through the first-level electronic component 110 and the gap fill material 140. Thus, the perimeter BEOL build-up structure regions surrounding the second-level components 130 can remain the final IC structure (package). The perimeter BEOL build-up structure regions may optionally be scribed off in the final IC structure (package) perimeter edges, though may remain in the space between laterally adjacent second-level components.

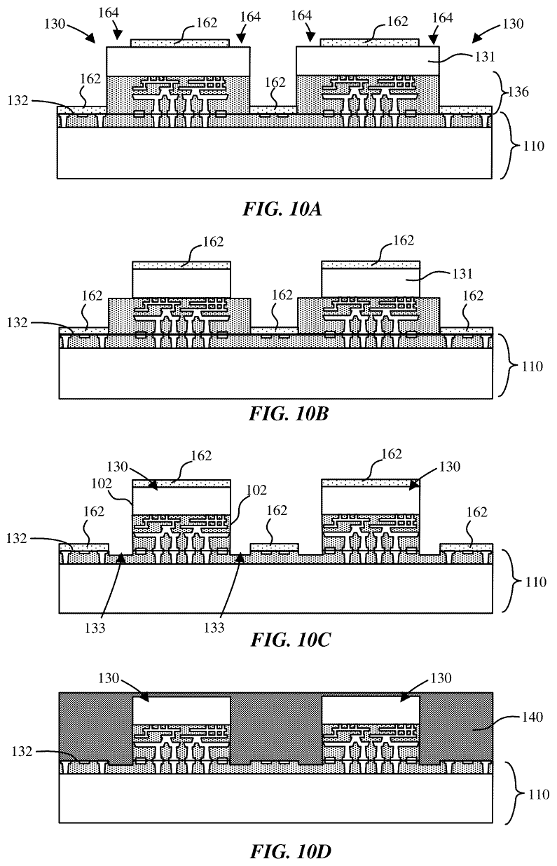

FIGS. 10A-10D are cross-sectional side view illustrations for a method of assembling an integrated circuit structure including plasma etching prior to molding in accordance with an embodiment. The process sequence of FIG. 10A and FIG. 10B is substantially the same as FIG. 9A and FIG. 9B. Referring to FIG. 10C, rather than forming a second mask layer, the plasma etching sequence can continue through the BEOL build-up structure 136 as shown in FIG. 10C stopping on the first-level bonding surface 132, or only minimally etching past the first-level bonding surface 132 to avoid damaging the first-level electronic component 110. Slight over etch may result in recesses 133 (e.g., several microns or less deep) around the plasma etched sidewalls 102 of the second-level components. Thus, the recesses are self-aligned with the plasma etched sidewalls 102. The second-level components 130 can then be encapsulated in gap fill material 140 (e.g., molding compound) as shown in FIG. 10D. The gap fill material 140 may also fill the recesses 133. Downstream IC structure (package) singulation can then be performed using traditional singulation/dicing techniques such as sawing through the first-level electronic component 110 and the gap fill material 140.

In utilizing the various aspects of the embodiments, it would become apparent to one skilled in the art that combinations or variations of the above embodiments are possible for packaging of an electronic component with plasma dicing. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. An integrated circuit structure comprising:
a first-level electronic component including a first-level bonding surface;
a first second-level component including a first second-level bonding surface bonded directly to the first-level bonding surface;
a gap fill material on the first-level bonding surface and laterally adjacent to the first second-level component; and
a plasma etched sidewall that spans across an entire thickness of the first-level electronic component and the first second-level component.

2. The integrated circuit structure of claim 1, wherein the plasma etched sidewall extends across an entire thickness of the gap fill material.

3. The integrated circuit structure of claim 2, further comprising a laser etched sidewall that extends across an entire thickness of the gap fill material.

4. The integrated circuit structure of claim 1, further comprising a second second-level component including a second second-level bonding surface bonded directly to the first-level bonding surface, wherein the gap fill material fills a space laterally between the first second-level component and the second second-level component, and the plasma etched sidewall spans across an entire thickness of the second second-level component.

5. The integrated circuit structure of claim 4, further comprising a laser etched sidewall that extends across an entire thickness of the gap fill material laterally between the first second-level component and the second second-level component, and terminates on the first-level component.

6. The integrated circuit structure of claim 5, wherein the gap fill material is a molding compound material.

7. The integrated circuit structure of claim 5, wherein the laser etched sidewall is a vertical cavity that extends internally into the integrated circuit structure from the plasma etched sidewall.

8. The integrated circuit structure of claim 5, further comprising a plasma etched recess sidewall that is recessed into the plasma etched sidewall, wherein the plasma etched recess sidewall spans across an entire thickness of the first second-level component and intersects with the laser etched sidewall.

9. The integrated circuit structure of claim 5, wherein a first portion of the laser etched sidewall extends laterally into the first second-level component and spans across an entire thickness of the first-level electronic component.

10. The integrated circuit structure of claim 9, wherein a second portion of the laser etched sidewall extends laterally into the second second-level component and spans across an entire thickness of the second second-level component.

11. The integrated circuit structure of claim 9, further comprising laser recast gap fill material on the laser etched sidewall.

12. The integrated circuit structure of claim 9, wherein the laser etched sidewall extends through the first-level bonding surface and into the first-level electronic component.

13. The integrated circuit structure of claim 9, wherein the first second-level component includes a back-end-of-the-line (BEOL) build-up structure, and a defect density within the BEOL build-up structure laterally adjacent to the laser etched sidewall is greater than a defect density within the BEOL build-up structure laterally adjacent to the plasma etched sidewall.

14. The integrated circuit structure of claim 4, wherein the first second-level component is hybrid bonded with the first-level electronic component, and the first second-level component is an integrated circuit (IC) die and the first-level electronic component is an interposer.

15. The integrated circuit structure of claim 14, wherein the second second-level component is a dummy die and is hybrid bonded or fusion bonded with the interposer.

16. A method of assembling an integrated circuit structure comprising:
directly bonding a first second-level bonding surface of a first second-level component to a first-level bonding surface of a first-level electronic component; encapsulating the first second-level component with a gap fill material on the first-level bonding surface; and
plasma dicing from a second side of the first-level electronic component opposite first-level bonding surface completely through the first-level electronic component and the first second-level component to singulate the integrated circuit structure.

17. The method of claim 16, further comprising:
directly bonding a second second-level bonding surface of a second second-level component to the first-level bonding surface of the first-level electronic component;
wherein the encapsulating comprises encapsulating the first second-level component and the second second-level component with the gap fill material on the first-level bonding surface; and
wherein the plasma dicing comprises plasma dicing from the second side of the first-level electronic component opposite first-level bonding surface completely through the first-level electronic component, the first second-level component, and the second second-level component to singulate the integrated circuit structure.

18. The method of claim 17, further comprising laser etching the gap fill material in a local area to locally remove the gap fill material from a space laterally between the first second-level component and the second second-level component prior to the plasma dicing.

19. The method of claim 18, wherein plasma dicing is through a dicing lane that intersects the local area, and wherein the dicing lane does not extend through a metal layer or the gap fill material where the gap fill material fills the space.

20. (canceled)

21. The method of claim 17, wherein the first-level electronic component is selected from the group consisting of a processed wafer including an array of interposers, a processed panel including an array of interposers, and a reconstituted substrate including an array of dies.

22. (canceled)

23. (canceled)

24. The method of claim 17, wherein directly bonding the first second-level bonding surface of the first second-level component to the first-level bonding surface of the first-level electronic component comprises hybrid bonding, and wherein directly bonding the second second-level bonding surface of the second second-level component to the first-level bonding surface of the first-level electronic component comprises dielectric-dielectric fusion bonding.

25-40. (canceled)
